(19) United States
(12) Patent Application Publication
(10) Pub. No.: US 2021/0383978 A1
(43) Pub. Date: Dec. 9, 2021

(54) RAPID HYBRID CHEMICAL VAPOR DEPOSITION FOR PEROVSKITE SOLAR MODULES

(71) Applicant: Okinawa Institute of Science and Technology School Corporation, Onna-son Okinawa (JP)

(72) Inventors: Yabing Qi, Onna-son Okinawa (JP); Longbin Qiu, Onna-son Okinawa (JP); Sisi He, Onna-son Okinawa (JP); Luis Katsuya Ono, Onna-son Okinawa (JP)

(21) Appl. No.: 17/339,005

(22) Filed: Jun. 4, 2021

Related U.S. Application Data
(60) Provisional application No. 63/036,068, filed on Jun. 8, 2020.

(51) Int. Cl. H01G 9/00; H01G 9/20; H01L 51/00; H01L 51/42; C23C 16/02; C23C 16/30; C23C 16/46

(52) U.S. Cl. CPC H01G 9/0036; H01G 9/2009; H01L 51/0002; C23C 16/463; C23C 16/0272; C23C 16/30; H01L 51/4253

(57) ABSTRACT

Systems and methods for performing a rapid hybrid chemical vapor deposition are described herein. In an embodiment, first type of precursor materials is deposited on a substrate. The substrate is placed in a receptacle of a heating device, the heating device configured to provide heat to at least a portion of the receptacle. A second type of precursor materials is placed in the receptacle of the heating device such that the organic compound is closer to a gas source of the heating device than the substrate. A gas flow is created through the receptacle of the heating device. The heating component is used to cause of a portion of the receptacle comprising the substrate and the second type of precursor materials. During the heating process, at least a portion of the second type of precursor materials is deposited on at least a portion of the first type of precursor materials on the substrate.

### BENEFIT CLAIM

This application claims the benefit under 35 U.S.C. § 119(e) of Provisional Application No. 63/036,068, filed Jun. 8, 2020, the entire contents of which are incorporated by reference for all purposes as if fully set forth herein.

### FIELD OF THE DISCLOSURE

The present disclosure relates to chemical vapor deposition techniques for creating Perovskite solar cells.

### BACKGROUND

The approaches described in this section are approaches that could be pursued, but not necessarily approaches that have been previously conceived or pursued. Therefore, unless otherwise indicated, it should not be assumed that any of the approaches described in this section qualify as prior art merely by virtue of their inclusion in this section. Further, it should not be assumed that any of the approaches described in this section are well-understood, routine, or conventional merely by virtue of their inclusion in this section.

Perovskite as a low-cost material is boosting the performance up to 25.2% for small area (0.09 cm²) single-junction solar cells and the expected levelized cost of electricity (LCOE) is as low as 3.5 US cents/kWh (as comparison, LCOE for grid power is 7.04-11.90 US cents/kWh and for c-Si solar cell is 9.78-19.33 US cents/kWh) when assuming a 1 m² module with 20% efficiency and >15 years lifetime, and this exceeds the 2030 goals of US Department of Energy of 5 US cents/kWh for residential solar power. Recently, there have been more and more works focusing on scalable fabrication of perovskite solar modules (PSMs) to transfer the desired performance from small area cells to large-area modules. However, there is still a large gap between small area cells and large-area modules.

To achieve scalable fabrication, a key indicator is the performance decay rate upon upscaling. For mature photovoltaic technologies (e.g., crystalline silicon solar cells, polycrystalline silicon solar cells, CdTe solar cells), the absolute performance decay rate is around 0.8%/decade area increase. If the same decay rate can be realized for perovskite photovoltaic technology, a power conversion efficiency (PCE) of approximately 22% would be expected for a module with the area of approximately 1000 cm² when scaling up from state of the art small area cells (25.2% PCE with a cell area of 0.0937 cm²). Currently the highest reported PCE for such a large-size PSM was 16.1% with a designated area of 802 cm². To reduce the large PCE gap between small area cells and large-area modules, scalable fabrication methods for perovskite and other functional layers (e.g., electron transport layer (ETL), hole transport layer (HTL), electrode and interface modification) are required. For the scalable fabrication of perovskite solar cells (PSCs), both solution- and vapor-based processes have been reported, including doctor blading, slot-die coating, spray coating, thermal evaporation and hybrid chemical vapor deposition (HCVD).

HCVD is a promising method as compared to the solution-based ones because of its advantages such as uniform deposition across large area, low cost, solvent-free, and readiness for integration with other thin film solar technologies (e.g., thin film silicon solar cells) to form tandem solar cells. Currently, the decay rate between small area cells and large area modules upon upscaling is 1.3%/decade area increase, which is approaching other mature photovoltaic technologies. HCVD is a two-step deposition process. In the first step, inorganic precursor materials (e.g., PbI₂, PbCl₂, CsI, etc.) is deposited by thermal evaporation, spray coating or spin coating. In the second step, organic precursor materials (e.g., FAI, MAI, MABr, etc., where FA is formamidinium and MA is methylammonium) is sublimed in the first heating zone of a CVD tube furnace, and subsequently driven by a gas flow (e.g., N₂, Ar, or dry air) towards the second heating zone, where the organic precursor vapor reacts with the inorganic precursor that is pre-deposited on the substrate, leading to perovskite film growth. Based on the pressure and zone temperatures, a variety of HCVD techniques can be developed to fabricate perovskite film including atmospheric pressure HCVD, low-pressure HCVD, single-zone HCVD and double-zone HCVD. However, all the HCVD processes usually take a relatively long processing time (2-3 hours), which severely limits mass-production capabilities for large-area solar cell fabrication. How to reduce deposition time is one of the challenges to be addressed for the further development of HCVD. Furthermore, it has been found that the longer deposition time has a detrimental effect on the ETL such as SnO₂ and TiO₂, which lowers solar module performance. Also, the hysteresis behavior was observed for the un-optimized interface between this ETL layer and the perovskite layer. The use of an additional buffer layer such as C₆₀ improves the HCVD processed solar cell performance by reducing the negative impact of vacuum annealing on ETL. However, this additional layer increases the cost and complexity of the deposition process.

### SUMMARY

The appended claims may serve as a summary of the disclosure.

### BRIEF DESCRIPTION OF THE DRAWINGS

FIG. 1 depicts an example structure for a planar perovskite solar cell.

FIG. 2 depicts an example device for generating a perovskite film.

FIG. 3 depicts an example rapid hybrid chemical vapor deposition process.

### DETAILED DESCRIPTION

In the following description, for the purposes of explanation, numerous specific details are set forth in order to provide a thorough understanding of the present invention. It will be apparent, however, that the present invention may be practiced without these specific details. In other instances, well-known structures and devices are shown in block diagram form in order to avoid unnecessarily obscuring the present invention.

General Overview

In an embodiment, a method for fabricating perovskite film comprises depositing a first type of precursor materials on a substrate; placing the substrate in a receptacle of a heating device, the heating device comprising a heating component configured to provide heat to at least a portion of the receptacle; placing a second type of precursor materials in the receptacle of the heating device such that the second type of precursor materials is closer to a gas source of the heating device than the substrate; creating a gas flow through the receptacle of the heating device; using the heating component, causing heating of a portion of the receptacle comprising the substrate and the second type of precursor materials; wherein during a heating process, at least a portion of the second type of precursor materials is deposited on at least a portion of the first type of precursor materials on the substrate.

In an embodiment, the heating device comprises a cooling component that is and the method further comprises, after completing the heating process, using the cooling component, causing cooling of a portion of the receptacle comprising the substrate. In an embodiment, the cooling component comprises one or more of fans, dry ice, or a method that provides cooled dry air flow. In an embodiment, the heating component comprises an infrared heating component. In an embodiment, one or more of the heating component or the cooling component are mechanically movable with respect to the receptacle and are moved into position to cause performance of the heating or cooling respectively.

In an embodiment the second type of precursor materials comprises formamidinium iodide, methylammonium iodide, methylammonium bromide or formamidinium bromide. In an embodiment the inorganic precursor materials comprise a layer comprising CsI and PbI₂. In an embodiment, the layer comprising CsI and PbI₂ is deposited through co-evaporation, spray-coating, doctor blading, or spin-coating. In an embodiment, the heating device further comprises a vacuum pump and a vacuum gauge and wherein the method further comprises controlling a vacuum level of the receptacle during the heating process using the vacuum pump and the vacuum gauge.

In an embodiment, a heating device comprises a receptacle configured to hold an inorganic precursor material on a substrate and an organic compound; a heating component that is configured to heat at least a portion of the receptacle comprising the substrate and the organic compound to cause creation of a perovskite layer on the substrate; a vacuum gauge configured to measure a vacuum level of the receptacle; and a vacuum pump configured to create at least a partial vacuum in the receptacle. In an embodiment, the heating component comprises an infrared heating component. In an embodiment, the heating component is mechanically movable with respect to the receptacle. In an embodiment, the heating device further comprises a cooling component that is configured to cause cooling of a portion of the receptacle comprising the substrate after creation of the perovskite layer on the substrate. In an embodiment, the cooling component comprises one or more of fans, dry ice, or an implement that provides cooled dry air flow. In an embodiment, the cooling component is mechanically movable with respect to the receptacle.

Perovskite Solar Cell Structure

In an embodiment, an n-i-p planar perovskite solar cell (PSC) structure is configured with a perovskite layer sandwiched between an electron transport layer (ETL) and a hole transport layer (HTL). In an embodiment, the PSC structure does not include mesoporous structures, thereby obviating the need for a high-temperature step to generate the PSC structure.

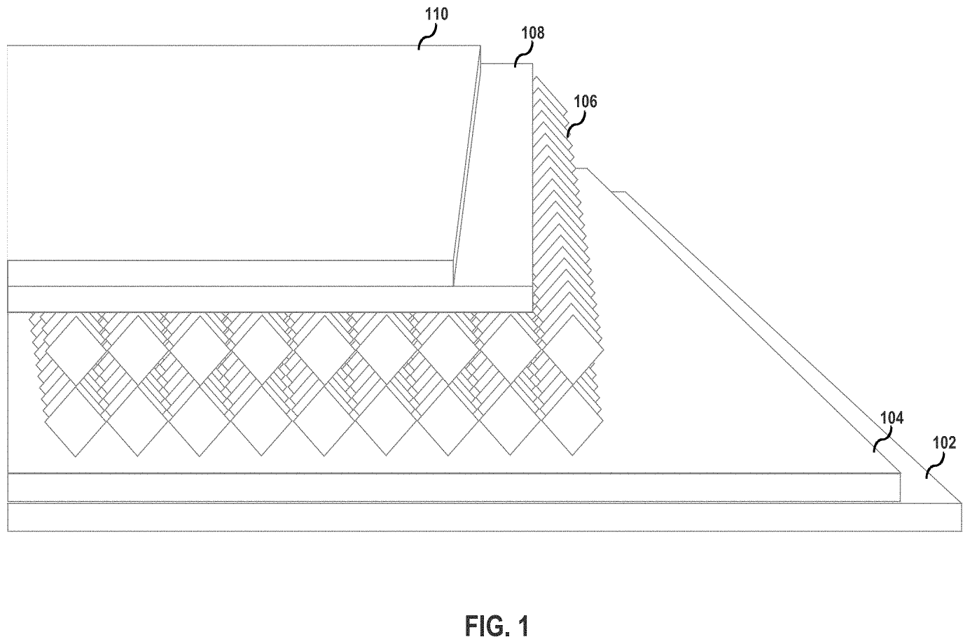

FIG. 1 depicts an example structure for a planar perovskite solar cell. In an embodiment, a planar perovskite solar cell 100 comprises a bottom layer 102 comprising indium-doped tin oxide (ITO) substrates, which corresponds to a transparent conductive oxide (TCO). The ITO substrates may be initially washed sequentially with distilled water, acetone, and isopropanol and dried with N₂ gas. A second layer 104 may comprise a tin dioxide (SnO₂) nanocrystal layer. The SnO₂ layer may be spin coated onto the ITO layer at a rate of 3000 rpm for 30 seconds, then dried, such as at a temperature of 150° C. for thirty minutes. While the TCO and ETL are depicted in FIG. 1 as comprising ITO and SnO₂ layers, respectively, other embodiments may comprise any TCO and ETL that are suitable for the rapid hybrid chemical vapor deposition (RHCVD) process described herein.

Perovskite layer 106 comprises a layer of inorganic precursor materials and organic precursor materials that are deposited onto the ETL using the systems and methods described herein. In an embodiment, perovskite layer 106 comprises a combination of cesium iodide, formamidinium (FA), and lead iodide. Other embodiments may comprise different combinations of organic and inorganic precursor materials, such as lead chloride for the inorganic material or methylammonium for the organic materials. An example composition of the perovskite layer is Cs_{0.1}FA_{0.9}PbI₃.

Hole transport layer 108 comprises a hole transport material that sits atop the perovskite layer 106. Hole transport layer 108 may be spin coated on top of perovskite layer 106, such as at a rotation speed of 300 rpm for 30 seconds. In an embodiment, hole transport layer 108 comprises a solution of spiro-MeOTAD, tributyl phosphate (TBP), and lithium bis(trisfluoromethanesulfonyl)imide (LiTFSI) in chlorobenzene. As a practical example, the solution may comprise 20 mg spiro-MeOTAD, 11.5 μL TBP, and 7 μL LiTFSI in 0.4 mL chlorobenzene. Top layer 110 may comprise a back-contact electrode, such as a layer of gold with a thickness of 100-120 nm.

Rapid Hybrid Chemical Vapor Deposition Device

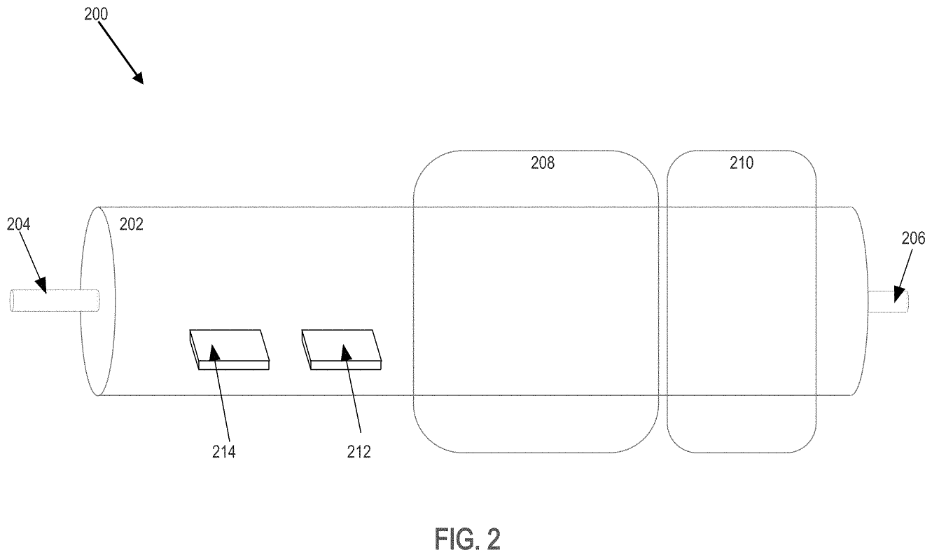

FIG. 2 depicts an example device for generating a perovskite solar module. In an embodiment, device 200 comprises a rapid-thermal annealing (RTA) tube furnace. Device 200 comprises a single-zone or multi-zone tube 202. The tube 202 may comprise any material that is capable of being heated to required temperatures and transferring heat to objects inside. An example tube 202 may be a quartz tube.

Input 204 comprises an opening in which a gas can be pumped into the tube 202. Input 204 may also comprise a location in which a vacuum gauge (not shown) may be placed to measure pressure inside tube 202. Output 206 comprises an opening which may be attached to a vacuum pump (not shown) to reduce pressure within tube 202. Output 206 may additionally provide an opening through which a gas may flow out of tube 202.

Heating system 208 comprises one or more heating apparatuses configured to provide heat to a section of tube 202. In an embodiment, heating system 208 comprises an infrared heating system. Heating system 208 may be mechanically free-moving with respect to tube 202 and/or attached to one or more rails that allow heating system 208 to move freely along a horizontal axis of tube 202. Movement of the heating system may be controlled mechanically or may be automatically controlled by a computing device.

Cooling system 210 comprises one or more cooling apparatuses configured to cool a section of tube 202. In an embodiment, cooling apparatus 210 comprises one or more fans. Cooling system 210 may be mechanically free-moving with respect to tube 202 and/or attached to one or more rails that allow cooling system 210 to move freely along a horizontal axis of tube 202. Movement of cooling system 210 may be controlled mechanically or may be automatically controlled by a computing device. In an embodiment, cooling system 210 and heating system 208 are attached, such that moving heating system 208 causes movement of cooling system 210.

Substrate 212 comprises one or more solar module substrates onto which a perovskite film is to be deposited using the methods described herein. In an embodiment, substrate 212 is placed on a platform within device 200. In an embodiment, the platform is controllable, thereby allowing the substrate to be moved within the device 200 during execution of the methods as described further herein. In an embodiment, the substrate 212 is precoated with inorganic precursor materials, such as a mixture of CsI and PbI₂.

Deposition materials 214 comprise organic precursor materials placed in device 200 for sublimation. The organic precursor materials may comprise a formamidinium iodide, a methylammonium iodide, a methylammonium bromide, or any other suitable organic precursor material. The organic precursor materials may be placed in an upstream position of the substrate 212 relative to a gas flow to be driven through the device 200. In an embodiment, deposition materials 213 are placed on a platform within device 200. In an embodiment, the platform is controllable, thereby allowing deposition materials to be moved within the device 200 during execution of the methods as described further herein.

Rapid Hybrid Chemical Vapor Deposition

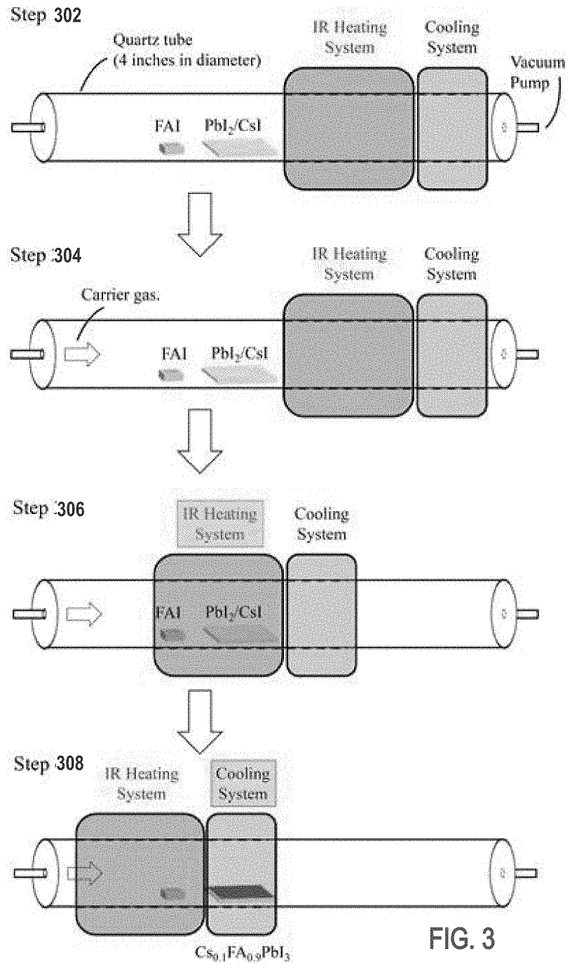

FIG. 3 depicts an example rapid hybrid chemical vapor deposition process. The example of FIG. 3 comprises one implementation of the rapid hybrid chemical vapor deposition methods described herein. Alternative examples may include different materials, different types of heating or cooling systems, different types of movement systems, multi-zone tubes, and/or other variations.

At step 302, a solar substrate module and deposition materials are placed in chamber. The chamber may comprise a chamber of any material suitable for the vacuum pressures and heating methods described herein. While the chamber is depicted as a cylindrical tube in FIG. 3, other shapes, such as a cuboid or hexagonal prism, may be used. Additionally, while the cylindrical tube is listed as being made from quartz, other materials may be used.

The solar substrate module may comprise an indium-doped tin oxide coated with an SnO₂ layer. The deposition materials may comprise an organic precursor material in powder form, such as 0.1 g of formamidinium iodide for a 5 cm×5 cm substrate module. The deposition materials may be placed such that the deposition materials are upstream of the solar substrate module with respect to a gas flow. For example, if a gas is pulled through the device through use of a vacuum pump, the deposition materials may be placed closer to the source of the gas than the solar substrate module such that the gas flow would reach the deposition materials prior to reaching the solar substrate module.

At step 304, a flow of carrier gas is created through the chamber. The carrier gas may be any suitable gas for creating an air flow, such as N₂, Ar, air, O₂, or other gases. The flow may be created using any suitable means for providing a gas flow. A vacuum pump may be used to generate pressure within the chamber. In an embodiment, a vacuum gauge is used to control the pressure level of the chamber. As an example, the vacuum level may be adjusted through use of the vacuum pump to remain at or near 10 Torrs.

At step 306, a heating system begins heating the solar substrate module and the deposition materials. For example, a moveable infrared heating system may be moved into a position such that heat would be applied directly to both the solar substrate module and the deposition materials. Additionally or alternatively, a heating system already in position to heat the solar substrate module and the deposition materials may be activated to begin the heating process. Additionally or alternatively, the solar substrate module and deposition materials may be moved into a position to be heated by the heating system, such as through a moving platform within the chamber. While FIG. 3 depicts the heating system as an infrared heating system, other systems may be used to heat both the solar substrate module and the deposition materials.

In an embodiment, the heating system and cooling system are configured to move together. For example, the heating system and cooling system may be attached to each other along a rail, such that the two systems may be moved along a horizontal axis of the chamber. In other embodiments, the heating and cooling system are stationary and the solar substrate module and deposition materials are moved along the horizontal axis of the chamber.

In an embodiment, the heating of step 306 may be performed for anywhere between one and twenty minutes. Reduced temperatures may correspond to higher perovskite conversion times. As an example, a temperature of 170° C. may be applied for two to three minutes while a temperature of 160° C. is applied for five to six minutes.

At step 308, the heating system stops heating the solar substrate module and the deposition materials and a cooling system begins cooling the solar substrate module. For example, the heating system may be turned off and the cooling system may be moved into a position to provide cooling to at least the solar substrate module. Additionally or alternatively, the solar substrate module may be moved to a position where the cooling system is capable of cooling the solar substrate module, such as through a moveable platform. The cooling system may comprise one or more fans or any other cooling system.

While embodiments have been described with respect to moveable heating and cooling systems and/or moveable platforms for the solar substrate module and deposition materials, other embodiments may include a chamber with stationary elements. For example, a cooling system and heating system may be configured to both target a same portion of the chamber. At step 306, the heating system may be activated, thereby applying heat to the solar substrate module and deposition materials. Then, at step 308, the heating system may be deactivated and the cooling system may be activated.

After performance of a rapid hybrid chemical deposition process, such as the process depicted in FIG. 3, the perovskite film may be washed and heated to remove any residual formamidinium iodide. A hole transport material may be spin-coated on top of the perovskite layer. After the hole transport layer is deposited on top of the perovskite, a back contact electrode may be added onto the hole transport layer, such as a 120 nm layer of gold.

### Benefits of Certain Embodiments

The systems and methods described herein improve the process of hybrid chemical vapor deposition to generate perovskite solar modules. The use of the rapid hybrid chemical vapor deposition process reduces deposition time for the perovskite layer from several hours to within ten minutes. The process may additionally be scaled to produce a greater number of perovskite solar modules at a time without significant efficiency reduction and with minimal hysteresis. Additionally, the use of an infrared heating system leads to better perovskite film quality compared to perovskite films post-annealed by conventional methods due to the dual function of IR heating in promoting perovskite formation as well as uniformly heating the converted perovskite films to enhance their crystallinity.

In addition, the shorter processing time inside the CVD tube furnace shortens the exposure time of the glass/ITO/SnO₂ electron-transport layer substrates in vacuum, which helps maintain the high quality of SnO₂ electron-transport layer with a low density of gap states. PSMs with a designated area of 22.4 cm² have been demonstrated with an efficiency of 12.3%. The performance of these PSMs maintains 90% of its initial value after operation at steady state power output under continuous light illumination for over 800 h.

The use of the n-i-p planar PSC structure with a perovskite layer between the ETL and HTL eliminates a need for a high-temperature process due to the lack of mesoporous structures. The use of a small amount of Cs cation improves the stability of the perovskite film.

What is claimed is:

1. A method for fabricating Perovskite solar cells comprising:
depositing a first type of precursor materials on a substrate;
placing the substrate in a receptacle of a heating device, the heating device comprising a heating component configured to provide heat to at least a portion of the receptacle;
placing a second type of precursor materials in the receptacle of the heating device such that the second type of precursor materials is closer to a gas source of the heating device than the substrate;
creating a gas flow through the receptacle of the heating device;
using the heating component, causing heating of a portion of the receptacle comprising the substrate and the second type of precursor materials;
wherein during a heating process, at least a portion of the second type of precursor materials is deposited on at least a portion of the first type of precursor materials on the substrate.

2. The method of claim 1, wherein the heating device comprises a cooling component wherein the method further comprises, after completing the heating process, using the cooling component, causing cooling of a portion of the receptacle comprising the substrate.

3. The method of claim 2, wherein the cooling component comprises one or more fans, dry ice, or cooled dry air flow.

4. The method of claim 2, wherein the cooling component is mechanically movable with respect to the receptacle and wherein causing cooling of the portion of the receptacle comprising the substrate comprises moving the cooling component into a position where activation of the cooling component causes cooling of the portion of the receptacle comprising the substrate.

5. The method of claim 1, wherein the heating component comprises an infrared heating component.

6. The method of claim 1, wherein the heating component is mechanically movable with respect to the receptacle and wherein causing heating of the portion of the receptacle comprising the substrate and the second type of the precursor material comprises moving the heating component into a position where activation of the heating component causes heating of the portion of the receptacle comprising the substrate and the second type of the precursor material.

7. The method of claim 1, wherein the second type of precursor materials comprises formamidinium iodide, methylammonium iodide, methylammonium bromide or formamidinium bromide.

8. The method of claim 1, wherein the first type of precursor materials comprise one or more of a CsI layer, a PbI₂ layer, a PbBr₂ layer, or a CsBr layer.

9. The method of claim 1, wherein the first type of materials comprises a layer comprising CsI and PbI₂ and wherein the layer comprising CsI and PbI₂ layer is deposited through co-evaporation, spray-coating, doctor blading, or spin-coating.

10. The method of claim 1, wherein the heating device further comprises a vacuum pump and a vacuum gauge and wherein the method further comprises controlling a vacuum level of the receptacle during the heating process using the vacuum pump and the vacuum gauge.

11. A heating device comprising:
a receptacle configured to hold an inorganic precursor material on a substrate and an organic compound;
a heating component that is configured to heat at least a portion of the receptacle comprising the substrate and the organic compound to cause creation of a perovskite layer on the substrate;
a vacuum gauge configured to measure a vacuum level of the receptacle; and
a vacuum pump configured to create at least a partial vacuum in the receptacle.

12. The heating device of claim 11, wherein the heating component comprises an infrared heating component.

13. The heating device of claim 11, wherein the heating component is mechanically movable with respect to the receptacle.

14. The heating device of claim 11, further comprising a cooling component that is configured to cause cooling of a portion of the receptacle comprising the substrate after creation of the perovskite layer on the substrate.

15. The heating device of claim 14, wherein the cooling component comprises one or more of fans, dry ice, or an implement that provides cooled dry air flow.

16. The heating device of claim 14, wherein the cooling component is mechanically movable with respect to the receptacle.
